(19) United States
(12) Patent Application Publication
(10) Pub. No.: US 2016/0300977 A1
(43) Pub. Date: Oct. 13, 2016

(54) SUBSTRATE OF PHOTOELECTRIC CONVERSION DEVICE AND METHOD OF MANUFACTURING THE SAME

(71) Applicant: SHIN SHIN NATURAL GAS CO., LTD., New Taipei (TW)

(72) Inventors: Sheng-Hui Chen, Taoyuan (TW); Shao-Ze Tseng, Taoyuan (TW); Chao-Yang Tsao, New Taipei (TW); Jenq-Yang Chang, Taoyuan (TW)

(21) Appl. No.: 14/919,715

(22) Filed: Oct. 21, 2015

(30) Foreign Application Priority Data
Apr. 10, 2015 (TW) 104111651

(51) Int. Cl. H01L 31/18; H01L 31/0445

(52) U.S. Cl. CPC H01L 31/1852; H01L 31/0445

(57) ABSTRACT

A manufacturing method of a substrate of a photoelectric conversion device includes the following steps. A single crystal silicon wafer is set into a chamber of a machine, wherein a germanium target or a silicon germanium target is disposed in the chamber. Thereafter, a physical vapor deposition process is performed to form a single crystal germanium thin film or a single crystal silicon germanium thin film on the single crystal silicon wafer. The manufacturing method reduces the production cost of substrates of photoelectric conversion devices. Furthermore, another substrate of a photoelectric conversion device is also provided.

### FIELD OF THE INVENTION

The present invention relates to a semiconductor substrate, and more particularly to a substrate of a photoelectric conversion device and a method of manufacturing the same.

### BACKGROUND OF THE INVENTION

In order to increase efficiency of solar cells, increasing the absorption rate of incident light is one of the basic methods. However, the wavelengths which a solar cell can absorb are determined by the band gap of the material of the solar cell. The spectrum of solar light is 250 nanometers to 2500 nanometers (nm). Currently, no single material is able to absorb light from this entire spectrum. Therefore, a multi-junction structure is a preferred choice for absorbing this wide spectrum.

However, regarding Groups III-V multi-junction solar cells, a disadvantage exists in its silicon substrate. Namely, the lattice constant of silicon is too small for Groups III-V, and therefore it is difficult to develop Groups III-V material of high quality and high crystallization rate on silicon. On the other hand, germanium has a good lattice matching to gallium arsenide. Even selecting compounds of gallium phosphide and indium phosphide to stack on a germanium substrate is a good option. Even though germanium has a good lattice matching and can be formed with a high quality gallium arsenide layer thereon, the band gap of germanium is overly low when using as a substrate for a multi-junction solar cell, produces overly high electric currents, and is unable to achieve a preferred current matching with a top layer of gallium phosphide or indium gallium phosphide (InGaP) of a multi-junction solar cell. Additionally, a germanium substrate also has disadvantages of high in production cost and poor in heat conduction.

### SUMMARY OF THE INVENTION

The present disclosure provides a method of manufacturing a substrate of a photoelectric conversion device, wherein the manufactured substrate can replace conventional germanium substrates.

The present disclosure provides a substrate of a photoelectric conversion device, to replace conventional germanium substrates.

The method of manufacturing a substrate of a photoelectric conversion device according to an embodiment of the present disclosure comprises the following steps: disposing a single crystal silicon wafer into a chamber of a machine, wherein the chamber has a germanium target or a silicon germanium target therein; and performing a physical vapor deposition, for forming a single crystal germanium thin film or a single crystal silicon germanium thin film on the single crystal silicon wafer.

In an embodiment of the present disclosure, the abovementioned method of manufacturing further comprises: before performing the physical vapor deposition (PVD), heating the single crystal silicon wafer to over 150 degrees Celsius (° C.), and adjusting a pressure inside the chamber to less than or equal to 9×10⁻⁶ Torr.

In an embodiment of the present disclosure, before performing the physical vapor deposition, the single crystal silicon wafer is heated to a temperature ranging between 200° C. and 500° C.

In an embodiment of the present disclosure, before performing the physical vapor deposition, the single crystal silicon wafer is heated to 300° C.

In an embodiment of the present disclosure, before performing the physical vapor deposition, the pressure inside the chamber is adjusted to less than or equal to 1×10⁻⁵ Torr.

In an embodiment of the present disclosure, during the physical vapor deposition, the pressure inside the chamber is less than or equal to 5×10⁻¹ Torr.

In an embodiment of the present disclosure, the physical vapor deposition includes sputtering deposition.

In an embodiment of the present disclosure, the method of manufacturing further comprises: before disposing the single crystal silicon wafer into the chamber, cleaning the single crystal silicon wafer.

In an embodiment of the present disclosure, the step of cleaning the single crystal silicon wafer includes: performing an RCA cleaning process, and immersing the single crystal silicon wafer in hydrofluoric acid.

In an embodiment of the present disclosure, the crystallographic direction of the single crystal silicon wafer is (100), (111), (220), (311), (222), (400), (311), or (422).

The substrate of the photoelectric conversion device of an embodiment of the present disclosure includes a single crystal silicon wafer and a single crystal thin film, wherein the single crystal thin film is disposed on the single crystal silicon wafer, and the single crystal thin film is a single crystal germanium thin film or a single crystal silicon germanium thin film.

In the method of manufacturing a substrate of a photoelectric conversion device according to the present disclosure, a conventional germanium substrate is replaced by a single crystal silicon wafer and a single crystal germanium thin film or a single crystal silicon germanium thin film formed thereon acting as a substrate of a photoelectric conversion device, thereby overcoming disadvantages of a germanium substrate.

The present disclosure will become more readily apparent to those ordinarily skilled in the art after reviewing the following detailed description and accompanying drawings.

### BRIEF DESCRIPTION OF THE DRAWINGS

FIG. 1 is a flowchart of a method of manufacturing a substrate of a photoelectric conversion device according to an embodiment of the present disclosure;

FIGS. 2A and 2B are schematic diagrams of a substrate of a photoelectric conversion device manufactured by a plasma sputtering machine according to an embodiment of the present disclosure; and

FIG. 3 is a schematic diagram of a substrate of a photoelectric conversion device according to an embodiment of the present disclosure.

### DETAILED DESCRIPTION OF PREFERRED EMBODIMENTS

A substrate of a photoelectric conversion device according to the present disclosure comprises a single crystal silicon wafer and a single crystal thin film disposed thereon, wherein the single crystal thin film can be a single crystal germanium thin film or a single crystal silicon germanium thin film. The following along with the figures describe a method of manufacturing a substrate of a photoelectric conversion device according to an embodiment of the present disclosure.

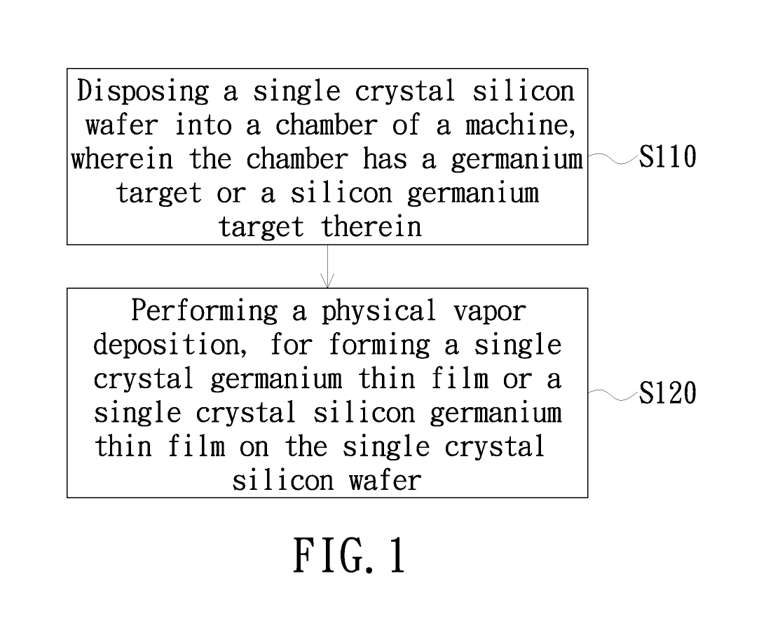

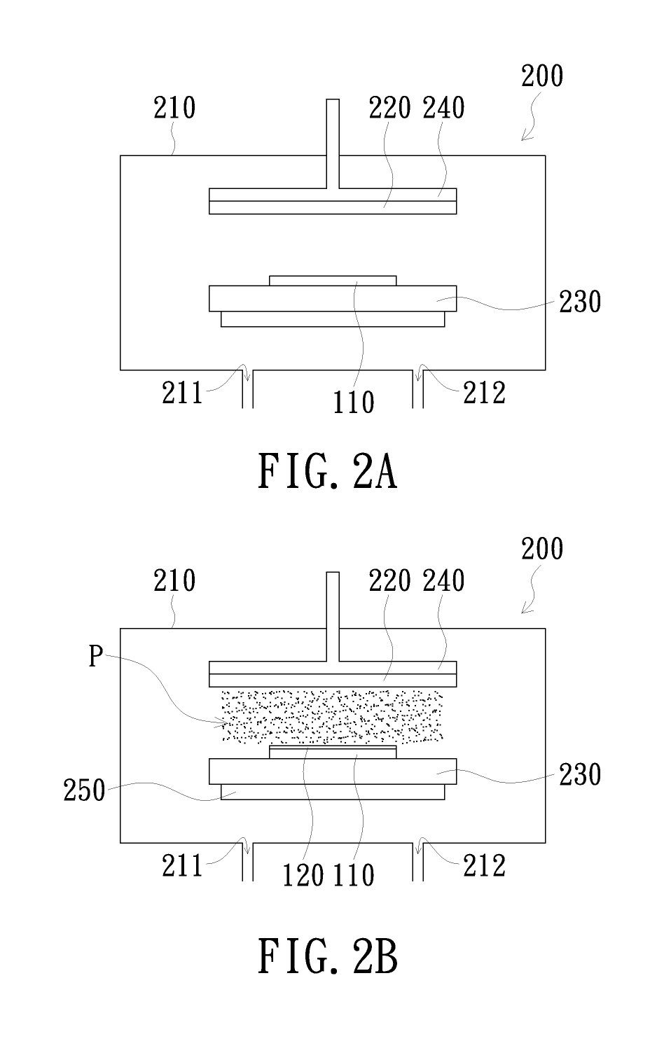

FIG. 1 shows a flowchart of a method of manufacturing a substrate of a photoelectric conversion device according to an embodiment of the present disclosure. FIG. 2A and FIG. 2B show schematic diagrams of a substrate of a photoelectric conversion device manufactured by a plasma sputtering machine according to an embodiment of the present disclosure. Referring to FIG. 1 and FIG. 2A, the method of manufacturing a substrate a substrate of a photoelectric conversion device according to the present embodiment comprises the following steps: first, as shown in step S110, a single crystal silicon wafer 110 is disposed into a chamber 210 of a machine 200, wherein the chamber 210 has a target 220. The target 220 can be a germanium target or a silicon germanium target. In FIG. 2A, the single crystal silicon wafer 110 and the target 220 are for example positioned between an anode 230 and a cathode 240 in the chamber 210, wherein the single crystal silicon wafer 110 is proximal to the anode 230, and the target 220 is proximal to the cathode 240. A crystallographic direction of the single crystal silicon wafer 110 can be (100), (111), (220), (311), (222), (400), (311) or (422). Additionally, the machine 200 is a physical vapor deposition machine, such as an evaporation machine or a sputtering machine, wherein the sputtering machine is categorized as a plasma sputtering machine, ion beam sputtering machine, etc. according to the source of sputtering. The present embodiment uses for example a plasma sputtering machine, but is not limited thereto. Additionally, the chamber 210 has an inlet 211 and an outlet 212, wherein the inlet 211 is configured to allow gas in, and the outlet 212 is for evacuating gas. 10024j In order to form high quality single crystal thin film in subsequent steps, prior to disposing the single crystal silicon wafer 110 into the chamber 210, the single crystal silicon wafer 110 can be cleaned. The step of cleaning the single crystal silicon wafer 110 includes for example firstly performing an RCA cleaning process, then immersing the single crystal silicon wafer 110 in hydrofluoric acid, followed by removal of a native oxide film on the single crystal silicon wafer 110. In an embodiment, the concentration of the hydrofluoric acid is about 1-5%, for example 2%, and the time of immersion is 1-5 minutes, for example 2 minutes, but can be adjusted according to needs and the present disclosure is not limited thereto.

Next, as shown by step S120 and in FIG. 2B, a physical vapor deposition is performed, forming a single crystal thin film 120 on the single crystal silicon wafer 110. The single crystal thin film 120 is a single crystal germanium thin film or a single crystal silicon germanium thin film. When forming the single crystal germanium thin film, the target 220 is a germanium target; and when forming a single crystal silicon germanium thin film, the target 220 is a silicon germanium target. In order to form the single crystal thin film 120 of high quality, prior to performing the physical vapor deposition, the single crystal silicon wafer 110 can be heated to over 150° C., and gas can be evacuated, such that a pressure inside the chamber 210 is less than or equal to 9×10⁻⁶ Torr. In an embodiment, the single crystal silicon wafer 110 can be heated to between 200 degrees ° C. and 500° C., e.g. 300° C. or 400° C. Additionally, the method of heating the single crystal silicon wafer 110 can include: heating the single crystal silicon wafer 110 to a predetermined temperature through a heater 250 inside the chamber 210, waiting for a period of time such that the temperature of the single crystal silicon wafer 110 stabilizes, and performing the physical vapor deposition. The wait time is about 5-15 minutes, e.g. 15 minutes, according to practical needs. Additionally, in an embodiment, prior to performing the physical vapor deposition, the pressure inside the chamber 210 can be adjusted to less than or equal to 1×10⁻⁵ Torr.

The physical vapor deposition of the present embodiment is for example a plasma sputtering, in which inert gas (such as argon) is filled into the chamber 210 through the inlet 211. Afterward, a high voltage is applied across the cathode 240 and the anode 230 to ionize gas molecules and form a plasma P. Thereby, through collision of cations in the plasma P (e.g. Ar⁺) with the target 220, the material of the target 220 sputters and deposits on the single crystal silicon wafer 110, thereby forming the single crystal thin film 120 on the single crystal silicon wafer 110. In order to increase the quality of the single crystal thin film 120, prior to performing the physical vapor deposition, the pressure inside the chamber 210 can be adjusted to less than or equal to 5×10⁻¹ Torr. Since plasma sputtering is a process familiar to people of ordinary skill in the art, it is not further described herein. Additionally, in some embodiments, evaporation machines can be used for the physical vapor deposition, and the present disclosure is not limited to a particular type of machine for performing physical vapor deposition. In another embodiment, a magnetron sputtering machine may be used for depositing on the single crystal think film 120, for increasing the quality of the single crystal thin film 120.

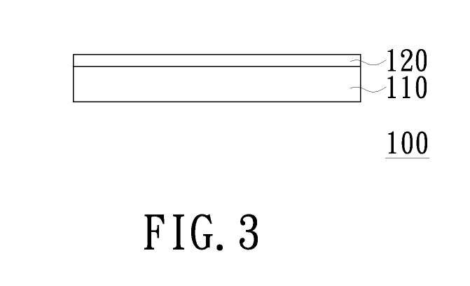

FIG. 3 shows a schematic diagram of a substrate of a photoelectric conversion device according to an embodiment of the present disclosure. Referring to FIG. 3, the substrate 100 of a photoelectric conversion device manufactured by the abovementioned method of manufacturing a substrate of a photoelectric conversion device includes the single crystal silicon wafer 110 and the single crystal thin film 120, wherein the single crystal thin film 120 is disposed on the single crystal silicon wafer 110, and the single crystal thin film 120 is a single crystal germanium thin film or a single crystal silicon germanium thin film. The crystallographic direction of the single crystal silicon wafer 110 is for example (100), (111), (220), (311), (222), (400), (311), or (422); and the crystallographic direction of the single crystal thin film 120 is substantially similar to the crystallographic direction of the single crystal silicon wafer 110.

In the abovementioned method of manufacturing, since the single crystal thin film 120 can be formed in an environment of a lower temperature, thermal strain defects caused by differences in coefficients of thermal expansion of silicon and germanium can be overcome. Moreover, relative to chemical vapor deposition, physical vapor deposition does not use toxic or flammable gasses, and therefore offers more protection of industrial safety. Additionally, the cost of a physical vapor deposition machine is much lower than that of a chemical vapor deposition machine, reducing the production cost of the substrate 100 of a photoelectric conversion device.

Moreover, the substrate 100 of a photoelectric conversion device of the present embodiment has the single crystal thin film 120 of low surface defects formed on the single crystal silicon wafer 110, thus suitable for replacing expensive germanium wafers. Applying the substrate 100 of a photoelectric conversion device to a solar cell or other photoelectric conversion devices is expected to reduce the production costs thereof. Additionally, other than applying the substrate 100 of a photoelectric conversion unit to a solar cell, since the lattice constant of germanium is similar to that of gallium arsenide, the objective of integrating Groups III-V semiconductor compound with silicon manufacturing techniques can be achieved, thereby enabling monolithical formation of a gallium arsenide photoelectric device on the substrate 100 of the photoelectric conversion device. Additionally, the energy band gap of germanium is lower than that of silicon and mainly absorbs wavelengths centered at the infrared section, and germanium has a greater mobility of electrons and electron holes than silicon does; and material properties of germanium and silicon are similar such that silicon manufacturing methods are easily integrated; therefore, germanium is more suitable, as compared with silicon, for application to optical components for long-distance optical communication. It is to be understood that the substrate 100 of a photoelectric conversion device according to the present disclosure is not limited to being applied to solar cells and optical components for long-distance optical communication.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A method of manufacturing a substrate of a photoelectric conversion device, comprising the steps of:
disposing a single crystal silicon wafer into a chamber of a machine, wherein the chamber has a germanium target or a silicon germanium target therein; and
performing a physical vapor deposition, for forming a single crystal germanium thin film or a single crystal silicon germanium thin film on the single crystal silicon wafer.

2. The method of manufacturing a substrate of a photoelectric conversion device according to claim 1, wherein prior to the step of performing the physical vapor deposition comprises:
heating the single crystal silicon wafer to over 150° C., and adjusting a pressure in the chamber to less than or equal to 9×10⁻⁶ Torr.

3. The method of manufacturing a substrate of a photoelectric conversion device according to claim 2, wherein prior to the step of performing the physical vapor deposition, the single crystal silicon wafer is heated to a temperature ranging between 200° C. and 500° C.

4. The method of manufacturing a substrate of a photoelectric conversion device according to claim 2, wherein prior to the step of performing the physical vapor deposition, the pressure in the chamber is adjusted to less than or equal to 1×10⁻⁵ Torr.

5. The method of manufacturing a substrate of a photoelectric conversion device according to claim 1, wherein during the physical vapor deposition, a pressure inside the chamber is less than or equal to 5×10⁻¹ Torr.

6. The method of manufacturing a substrate of a photoelectric conversion device according to claim 1, wherein the physical vapor deposition comprises sputtering deposition.

7. The method of manufacturing a substrate of a photoelectric conversion device according to claim 1, wherein prior to the step of disposing the single crystal silicon wafer into the chamber comprises:
cleaning the single crystal silicon wafer.

8. The method of manufacturing a substrate of a photoelectric conversion device according to claim 7, wherein the step of cleaning the single crystal silicon wafer comprises:
performing an RCA cleaning process; and
immersing the single crystal silicon wafer in hydrofluoric acid.

9. The method of manufacturing a substrate of a photoelectric conversion device according to claim 1, wherein a crystallographic direction of the single crystal silicon wafer is (100), (111), (220), (311), (222), (400), (311) or (422).

10. A substrate of a photoelectric conversion device, comprising:
a single crystal silicon wafer; and
a single crystal thin film, disposed on the single crystal silicon wafer, wherein the single crystal thin film is a single crystal germanium thin film or a single crystal silicon germanium thin film.
